(19) United States
(12) Patent Application Publication
(10) Pub. No.: US 2026/0190977 A1
(43) Pub. Date: Jul. 2, 2026

(54) SMART IC SUBSTRATE MODULE AND SMART IC SUBSTRATE

(71) Applicant: LG INNOTEK CO., LTD., Seoul (KR)

(72) Inventors: Jung Hun OH, Seoul (KR); Chae Hwan LIM, Seoul (KR); Jeong Min HYEON, Seoul (KR)

(21) Appl. No.: 18/833,963

(22) PCT Filed: Jan. 11, 2023
(86) PCT No.: PCT/KR2023/000525

§ 371 Date: Jul. 29, 2024

(30) Foreign Application Priority Data
Jan. 28, 2022 (KR) 10-2022-0012766

(51) Int. Cl. H10W 20/43

(52) U.S. Cl. CPC H10W 20/43

(57) ABSTRACT

A smart IC substrate module according to an embodiment a substrate including a first region and a second region disposed on and below the first region; a circuit layer disposed in the first region; and a conductive layer disposed in the first region and the second region and connected to the circuit layer, and an area of a conductive layer disposed in the second region is 20% or more of a total area of the second region.

### TECHNICAL FIELD

An embodiment relate to a smart IC substrate module and a smart IC substrate.

### BACKGROUND ART

An IC card is formed by combining a smart IC module and a card module. The smart IC module is formed by mounting a chip on a smart IC substrate.

The smart IC module is a substrate on which an IC that stores personal security information required for electronic residence cards, credit card USIMs, etc. is mounted. The smart IC can transmit the information to a reader in a form of an electrical signal.

The smart IC module may be classified into a single type and a dual type according to a structure of the substrate. In addition, the smart IC module may be classified into a contact type, a contactless type, a hybrid type, and a combi type according to a form of a card used.

The contact type is a method of transmitting and receiving information by physical contact. In addition, the contactless type is a method of transmitting and receiving information without physical contact. In addition, the combi type and the hybrid type are a method that includes both the physical contact function and the NFC function without physical contact.

The smart IC substrate includes a substrate and a plurality of circuit patterns on the substrate. The circuit pattern is connected to a chip.

A plating layer may be disposed on the circuit pattern. The plating layer may protect the circuit pattern. In addition, the plating layer may form a color. The circuit pattern may be connected to a plating line. Current may be transferred to the circuit pattern through the plating line. Accordingly, the plating layer may be formed on the circuit pattern.

If the current transmitted through the plating line is non-uniform, a thickness deviation of the plating layer may occur. Alternatively, if an overcurrent is transmitted through the plating line, the process efficiency of the plating layer may be reduced.

Therefore, a smart IC substrate module and a smart IC substrate with a new structure capable of solving the problems are required.

### DISCLOSURE

### Technical Problem

An embodiment is to provide a smart IC substrate module and a smart IC substrate having improved plating characteristics.

### Technical Solution

A smart IC substrate module according to an embodiment a substrate including a first region and a second region disposed on and below the first region; a circuit layer disposed in the first region; and a conductive layer disposed in the first region and the second region and connected to the circuit layer, and an area of a conductive layer disposed in the second region is 20% or more of a total area of the second region.

### Advantageous Effects

A smart IC substrate module according to an embodiment includes a second conductive layer. The second conductive layer transfers current to a circuit layer. In addition, an area and line width of the second conductive layer may be controlled.

Since the area of the second conductive layer is formed in a set range, a flow of current moving through the second conductive layer may be made uniform. In addition, it is possible to prevent an overcurrent from flowing in a specific region of the second conductive layer.

In addition, a line width of a pattern part of the second conductive layer is formed in a set range. In addition, a size of the line width of the pattern part of the second conductive layer is changed. Accordingly, the flow of current moving through the second conductive layer becomes uniform. That is, an area of the pattern part may be formed to be large or small according to a magnitude of the current moving through the second conductive layer. Accordingly, the current may stably move through the second conductive layer.

Accordingly, the current transmitted to the circuit pattern becomes uniform. Accordingly, it is possible to prevent a defect in the plating layer formed on the circuit pattern. Also, a thickness of the plating layer may be made uniform.

### DESCRIPTION OF DRAWINGS

FIG. 1 is a top view of a smart IC substrate module according to an embodiment.

FIG. 2 is an enlarged view of a region A of FIG. 1

FIG. 3 is an enlarged view of a region B of FIG. 1.

FIG. 4 is a top view of a first surface of a smart IC substrate according to an embodiment.

FIG. 5 is a top view of a second surface of a smart IC substrate according to an embodiment.

FIG. 6 is a top view of a bonding surface of a smart IC module in which a chip is disposed on a second surface of a smart IC substrate.

FIG. 7 is a cross-sectional view taken along line C-C′ region of FIGS. 4 and 6.

FIG. 8 is a view illustrating another cross-sectional view taken along line C-C′ region of FIGS. 4 and 6.

FIG. 9 is a top view of an IC card including a smart IC substrate according to an embodiment.

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and replaced.

In addition, unless expressly otherwise defined and described, the terms used in the embodiments of the present disclosure (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, a smart IC substrate module and a smart IC substrate including the same according to an embodiment will be described with reference to the drawings.

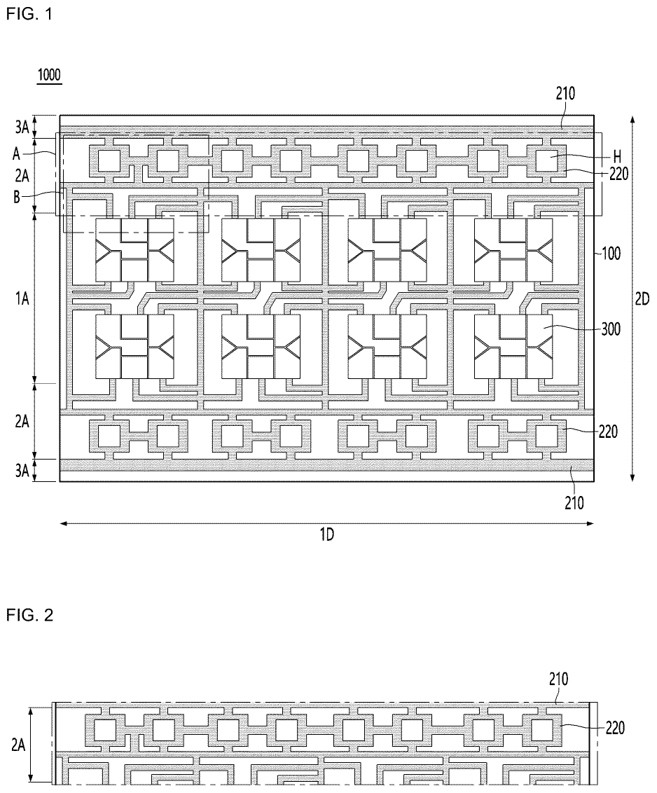

FIG. 1 is a top view of a smart IC substrate module according to an embodiment.

Referring to FIG. 1, a smart IC substrate module according to an embodiment includes a substrate 100, a conductive layer, and a circuit layer. The conductive layer and the circuit layer are disposed on the substrate 100.

The substrate 100 may include a resin material. The substrate 100 may include a prepreg including a glass fiber. In detail, the substrate 100 includes an epoxy resin, a glass fiber, and a silicon-based filler. The glass fiber and the silicon-based filler are dispersed in the epoxy resin.

The substrate 100 may be rigid or flexible. For example, the substrate 100 may include a glass or a plastic. In detail, the substrate 100 may include a chemically reinforced glass or semi-reinforced glass such as soda lime glass or aluminosilicate glass. Alternatively, the substrate 100 may include a reinforced plastic or a flexible plastic such as polyimide (PI), polyethylene terephthalate (PET), propylene glycol (PPG) or polycarbonate (PC). Alternatively, the substrate 100 may include sapphire.

Also, the substrate 100 may include a photo isotropic film. For example, the substrate 100 may include cyclic olefin copolymer (COC), cyclic olefin polymer (COP), photo isotropic polycarbonate (PC), or photo isotropic polymethyl methacrylate (PMMA).

In addition, the substrate 100 may be partially bent having a curved surface. That is, the substrate 100 may partially have a plane and may be partially bent having a curved surface. In detail, an end of the substrate 100 may be bent while having a curved surface.

Furthermore, the substrate 100 may be a flexible substrate having flexible characteristics. Furthermore, the substrate 100 may be a curved or bent substrate.

The substrate 100 may include a first direction 1D and a second direction 2D. For example, the first direction 1D may be defined in a longitudinal direction of the substrate 100. Also, the second direction 2D may be defined in a width direction of the substrate 100.

The substrate 100 may include a plurality of regions. In detail, the substrate 100 may include a first region 1A, a second region 2A, and a third region 3A.

The first region 1A may be disposed in a central region of the substrate 100. In addition, the second region 2A may be disposed in an upper region and a lower region of the substrate 100. The second region 2A may be disposed in an upper region and a lower region of the first region 1A. That is, the first region 1A may be disposed between the second regions 2A. In addition, the third region 3A may be disposed in the upper region and the lower region of the substrate 100. Specifically, the third region 3A may be disposed in an upper region and a lower region of the second region 2A. That is, the second region 2A may be disposed between the first region 1A and the third region 3A.

A first conductive layer 210 may be disposed in the third region 3A. Also, a plurality of sprocket holes H and the second conductive layer 220 may be disposed in the second region 2A. Also, a circuit layer 300 and a portion of the second conductive layer 220 may be disposed in the first region 1A.

The smart IC substrate simulation may be wound or unwound by the sprocket hole in a roll-to-roll method.

Conductive layers 210 and 220 and a circuit layer 300 are disposed on the substrate 100.

The first conductive layer 210, the second conductive layer 220, and the circuit layer 300 are connected to each other.

Specifically, the first conductive layer 210 may be disposed in the third region 3A. Furthermore, the second conductive layer 220 may be disposed in the second region 2A.

Furthermore, the second conductive layer 220 and the circuit layer 300 may be disposed in the first region 1A.

The first conductive layer 210 may be defined as an electric conductive layer. In detail, an electric roller moves on the substrate 100. The electric roller applies current. The electric roller contacts the first conductive layer 210. Accordingly, current is transmitted through the first conductive layer 210.

The current transferred to the first conductive layer 210 is transferred to the second conductive layer 220 connected to the first conductive layer 210.

The second conductive layer 210 may be defined as a lead-in layer. In detail, the second conductive layer 220 transfers a current to the circuit layer 300 connected to the second conductive layer 220.

The circuit layer 300 receives current from the first conductive layer 210 and the second conductive layer 220. Accordingly, a plating layer may be formed on the circuit layer 300.

Meanwhile, a resistance of the current moving through the first conductive layer and the second conductive layer may be changed according to a line width of the conductive layer. For example, as the line width of the conductive layer decreases, the resistance increases. In addition, when an area of the conductive layer is small, an overcurrent may be transferred to a specific region of the conductive layer.

Accordingly, defects in the plating layer may occur. In addition, a thickness of the plating layer may become non-uniform.

The smart IC substrate module according to an embodiment described below may solve the above problems.

Referring to FIGS. 1 and 2, the second conductive layer 220 may be disposed to have an area within a set range. In detail, the second conductive layer 220 may have an area of 20% or more of a total area of the second region 2A. In more detail, the second conductive layer 220 may have an area of 25% or more of the total area of the second region 2A. In more detail, the second conductive layer 220 may have an area of 20% to 30% of the total area of the second region 2A.

If the area of the second conductive layer 220 is less than 20% of the total area of the second region 2A, an area through which the current transferred to the second conductive layer 220 through the first conductive layer 210 may move is reduced. Accordingly, the resistance may increase. In addition, an overcurrent may flow at a specific region of the second conductive layer 220. Accordingly, the flow of current may become non-uniform.

Furthermore, if the area of the second conductive layer 220 exceeds 30% of the total area of the second region 2A, an effect of improving the current flow is small. Furthermore, the process cost of forming the second conductive layer 220 is increased. Furthermore, when the second conductive layer 220 is formed in a plurality of patterns, a spacing between the patterns may be narrowed, and thus a short circuit may occur.

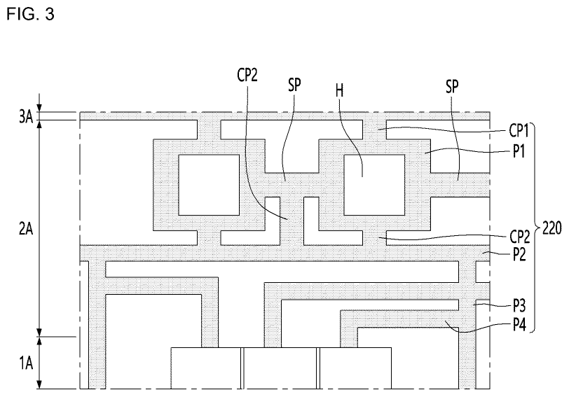

Referring to FIGS. 1 to 3, the second conductive layer 220 may include a plurality of pattern parts. Specifically, the second conductive layer 220 may include a first pattern part P1, a second pattern part P2, a third pattern part P3, and a fourth pattern part P4. Also, the second conductive layer 220 may include a first connection pattern part CP1 and a second connection pattern part CP2.

The first pattern part P1 may be disposed in the second region 2A. Specifically, the first pattern part P1 may be disposed only in the second region 2A.

The first pattern part P1 may be disposed closer to the first conductive layer 210 than the second pattern part P2 and the third pattern part P3. The first pattern part P1 may be connected to the first conductive layer 210 by the first connection pattern part CP1.

The first pattern part P1 may be adjacent to a sprocket hole H. The first pattern part P1 may be disposed to surround the sprocket hole H. That is, a shape of the first pattern part P1 may correspond to a shape of the sprocket hole H. That is, the sprocket hole H may be disposed in an inner region of the first pattern part P1.

The first pattern part P1 may include a plurality of first pattern parts. For example, the first pattern part P1 may include a plurality of first pattern parts P1 spaced apart from each other in the first direction 1D.

A reinforcing pattern part SP may be disposed between the first pattern parts P1. The reinforcing pattern part SP may be connected to the first pattern parts P1 adjacent to each other. Accordingly, the flow of current moving through the second conductive layer 220 may be uniform. That is, a path through which a current may move may be formed by the reinforcing pattern part SP between the first pattern parts P1. Accordingly, an overcurrent may be prevented from flowing to any one of the plurality of first pattern parts P1.

The reinforcing pattern part SP may be connected to the second pattern part P2 by the second connection pattern part CP2.

The second pattern part P2 may be disposed close to the first pattern part P1. The second pattern part P2 may be connected to the first pattern part P1 by the second connection pattern part CP2.

The second pattern part P2 may extend in one direction. In detail, the second pattern part P2 may extend in the first direction 1D.

The second pattern part P2 may be disposed in the second region 2A. Specifically, the second pattern part P2 may be disposed only in the second region 2A.

The third pattern part P3 may be disposed close to the second pattern part P2. The third pattern part P3 may be connected to the second pattern part P3. That is, the second pattern part P2 and the third pattern part P3 may be directly connected to each other.

The third pattern part P3 may extend in one direction. In detail, the third pattern part P3 may be disposed to extend in the second direction 2D.

The third pattern part P3 may be disposed in at least one of the first region 1A and the second region 2A. Specifically, the second pattern part P2 may be disposed in both the first region 1A and the second region 2A.

The third pattern part P3 may include a plurality of third pattern parts P3. Specifically, the third pattern part P3 may include a plurality of third pattern parts P3 spaced apart from each other in the first direction 1D. Each of the plurality of third pattern parts P3 may be directly connected to the second pattern part P2. Also, a circuit layer 300 disposed on the first region 1A may be disposed between adjacent third pattern parts P3.

The fourth pattern part P4 may be connected to the third pattern part P3. That is, the third pattern part P3 and the fourth pattern part P4 may be directly connected to each other.

The fourth pattern part P4 may extend in multiple directions. In detail, the fourth pattern part P4 may include at least one bent portion. For example, the bent portion may be bent toward the circuit layer 300.

The fourth pattern part P4 may include a plurality of fourth pattern parts P4. In detail, each of the fourth pattern parts P4 may be connected to a pattern of the circuit layer 300. Accordingly, the current moving through the second conductive layer 220 may be transferred to a plurality of patterns of the circuit layer 300 through the first pattern part P1, the second pattern part P2, the third pattern part P3, and the fourth pattern part P4.

At least one pattern part among the first pattern part P1, the second pattern part P2, the third pattern part P3, the fourth pattern part P4, the first connection pattern part CP1, and the second connection pattern part CP2 may have a line width within a set range. Specifically, the line width of at least one pattern part among the first pattern part P1, the second pattern part P2, the third pattern part P3, the fourth pattern part P4, the first connection pattern part CP1, and the second connection pattern part CP2 may be 0.3 mm, 0.4 mm, 0.5 mm or 0.6 mm or more. In more detail, the line width of at least one pattern part among the first pattern part P1, the second pattern part P2, the third pattern part P3, the fourth connection pattern part CP4, and the second connection pattern part CP2 may be 0.3 mm to 0.7 mm. In more detail, the line width of at least one pattern part among the first pattern part P1, the second pattern part P2, the third pattern part P3, and the fourth pattern part P4 may be 0.4 mm to 0.6 mm.

If the line width of at least one pattern part among the first pattern part P1, the second pattern part P2, the third pattern part P3, the fourth pattern part P4, the first connection pattern part CP1, and the second connection pattern part CP2 is less than 0.4 mm, a movement path of the current moving in the second conductive layer 220 is reduced. Accordingly, the flow of the current may become non-uniform. Also, if the line width of at least one pattern part among the first pattern part P1, the second pattern part P2, the third pattern part P3, the fourth pattern part P4, the first connection pattern part CP1, and the second connection pattern part CP2 is greater than 0.6 mm, a spacing between the pattern parts is narrowed. Accordingly, the short circuit may occur due to an error during a process.

The first pattern part P1, the second pattern part P2, the third pattern part P3, the fourth pattern part P4, the first connection pattern part CP1, and the second connection pattern part CP2 may be formed to have different line widths. Specifically, the first pattern part P1, the second pattern part P2, the third pattern part P3, the fourth pattern part P4, the first connection pattern part CP1, and the second connection pattern part CP2 may be formed to have different line widths in the above-described line width range.

For example, the line width of the first connection pattern part CP1 may be greater than the line width of other pattern parts. The first connection pattern part CP1 is a pattern part connected to the first conductive layer 210. Accordingly, the first connection pattern part CP1 receives a current applied to the first conductive layer 210 from the electric roller. Accordingly, a higher current moves in the first connection pattern part CP1 than in other pattern parts. Accordingly, an overcurrent may be transferred to the first connection pattern part CP1. Also, the resistance of the first connection pattern part CP1 may be increased. Accordingly, the line width of the first connection pattern part CP1 is formed to be greater than the line width of the other pattern part. Accordingly, an overcurrent and an increase in resistance may be prevented.

Also, the line width of the second pattern part P2 and the third pattern part P4 may be greater than the line width of the fourth pattern part P4.

The second pattern part P2 is a region through which the current of the first pattern part P1 moves. Also, the third pattern part P3 is a region through which the current is transferred to a plurality of fourth pattern parts P4. Accordingly, the second pattern part P2 and the third pattern part P3 may move more current than the fourth pattern part P4.

Accordingly, the line widths of the second pattern part P2 and the third pattern part P3 are formed to be greater than the line widths of the fourth pattern part P4. Accordingly, an increase in resistance due to overcurrent may be prevented. Also, the non-uniformity of current may be prevented.

Meanwhile, a length of the first connection pattern part CP1 may have a set length. In detail, the length of the first connection pattern part CP1 may be 0.4 mm or more. In more detail, the length of the first connection pattern part CP1 may be 0.4 mm to 0.8 mm. In more detail, the length of the first connection pattern part CP1 may be 0.5 mm to 0.7 mm.

If the length of the first connection pattern part CP1 is less than 0.4 mm, a scratch may be formed on the surface of the first connection pattern part CP1. Specifically, when a current is applied to the first conductive layer 210 through the electric roller, a portion of the electric roller may also be in contact with the first connection pattern part CP1. Accordingly, a scratch may be formed on a surface of the first connection pattern part CP1. Therefore, it may affect the current flow of the first connection pattern part CP1. Also, when the length of the first connection pattern part CP1 is greater than 0.8 mm, the length of the first connection pattern part CP1 is increased. Accordingly, an area of the second region 2A may be increased.

A smart IC substrate module according to an embodiment includes a second conductive layer. The second conductive layer transfers current to a circuit layer. In addition, an area and line width of the second conductive layer may be controlled.

Since the area of the second conductive layer is formed in a set range, a flow of current moving through the second conductive layer may be made uniform. In addition, it is possible to prevent an overcurrent from flowing in a specific region of the second conductive layer.

In addition, a line width of a pattern part of the second conductive layer is formed in a set range. In addition, a size of the line width of the pattern part of the second conductive layer is changed. Accordingly, the flow of current moving through the second conductive layer becomes uniform. That is, an area of the pattern part may be formed to be large or small according to a magnitude of the current moving through the second conductive layer. Accordingly, the current may stably move through the second conductive layer.

Accordingly, the current transmitted to the circuit pattern becomes uniform. Accordingly, it is possible to prevent a defect in the plating layer formed on the circuit pattern. Also, a thickness of the plating layer may be made uniform.

Hereinafter, a smart IC substrate 2000 manufactured by the smart IC substrate module 1000 will be described with reference to the drawings.

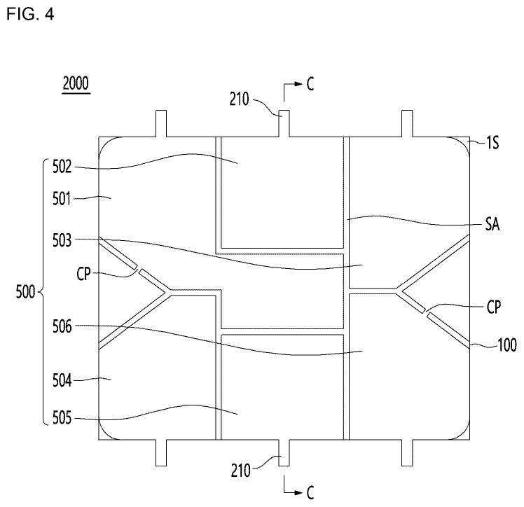

Referring to FIGS. 4 to 7, the substrate 100 may include a first surface 1S and a second surface 2S opposite to the first surface 1S. A chip is mounted on the smart IC substrate 2000. Accordingly, a smart IC module may be formed. The first surface 1S may be a contact side of the smart IC substrate 2000. Also, the second surface 2S may be a bonding side of the smart IC substrate 2000.

That is, the first surface 1S is a surface capable of recognizing information on the smart IC module through direct or indirect contact. Furthermore, a chip is mounted on the second surface 2S, and is adhered to a card body 2000.

The adhesive layer 400 may be disposed on at least one of the first surface 1S and the second surface 2S. The adhesive layer 400 may be entirely disposed on at least one of the first surface 1S and the second surface 2S. Specifically, the adhesive layer 400 may be disposed in a region other than a region in which the via is formed.

The adhesive layer 400 may include a resin material. For example, the adhesive layer 400 may include at least one of an epoxy resin, an acrylic resin, and a polyimide resin. In addition, the adhesive layer 400 may further include an additive. The additive may include a flame retardant such as a natural rubber, a plasticizer, a curing agent, or phosphorus-based material. Accordingly, flexibility of the adhesive layer 400 may be increased.

The circuit pattern 500 may be disposed on the substrate 100. The circuit pattern 500 may be disposed on at least one of the first surface 1S and the second surface 2S. For example, the circuit pattern 500 may be disposed on the first surface 1S. That is, the circuit pattern 500 may be disposed on a contact surface of the smart IC substrate.

The circuit pattern 500 may be disposed on the adhesive layer 400.

The circuit pattern 500 may include a first metal layer 510 and a second metal layer 520. Specifically, the first metal layer 510 is disposed on the adhesive layer 400. Also, the second metal layer 520 is disposed on the first metal layer 510.

The first metal layer 510 may correspond to the circuit layer 300 described above. Also, the second metal layer 520 may correspond to the plating layer described above.

The first metal layer 510 may include a metal material. Specifically, the first metal layer 510 may include a metal material having high electrical conductivity. For example, the first metal layer 510 may include at least one of gold (Au), silver (Ag), platinum (Pt), titanium (Ti), tin (Sn), copper (Cu), and zinc (Zn). Preferably, the first metal layer 310 may include copper (Cu).

The second metal layer 520 may protect the first metal layer 510. That is, corrosion of the first metal layer 510 may be prevented by the second metal layer 520. That is, the second metal layer 520 may be a protective layer of the circuit pattern 500.

The second metal layer 520 may include nickel-gold (Ni—Au) or nickel-palladium (Ni—Pd). For example, a nickel (Ni) layer may be formed on the first metal layer 510, and then a gold (Au) layer may be disposed on the nickel layer. A nickel-gold alloy layer may be formed between the nickel layer and the gold layer. Alternatively, a nickel layer may be formed on the first metal layer 510, and then a palladium layer may be disposed on the nickel layer. A nickel-palladium alloy layer may be formed between the nickel layer and the palladium layer.

The first metal layer 510, the second metal layer 520, and the adhesive layer 400 may have different thicknesses.

Specifically, a thickness of the first metal layer 510 may be greater than a thickness of the second metal layer 520 and a thickness of the adhesive layer 400. Also, a thickness of the adhesive layer 400 may be greater than a thickness of the second metal layer 520.

For example, the thickness of the first metal layer 510 may be 35 μm to 70 μm. Also, the thickness of the second metal layer 520 may be 1 μm to 3 μm. Also, the thickness of the adhesive layer 400 may be 15 μm to 30 μm.

Referring to FIG. 4, the circuit pattern 500 may include a plurality of circuit patterns. Specifically, the plurality of circuit patterns may be spaced apart from each other.

Referring to FIG. 4, the circuit pattern 500 may include a first circuit pattern 501, a second circuit pattern 502, a third circuit pattern 503, a fourth circuit pattern 504, a fifth circuit pattern 505, and a sixth circuit pattern 506. However, embodiments are not limited thereto. The circuit pattern 500 may include various numbers of circuit patterns.

The circuit patterns 501, 502, 503, 504, 505, and 506 are spaced apart from each other.

Specifically, space regions SA are formed between the circuit patterns 501, 502, 503, 504, 505, and 506. The circuit patterns 501, 502, 503, 504, 505, and 506 may be spaced apart from each other by the space regions SA. That is, the space region SA may be a spacing between the circuit patterns 501, 502, 503, 504, 505, and 506.

The space region SA may have a predetermined size. For example, the space region SA may be in a range of 0.1 mm to 0.5 mm.

Accordingly, the circuit patterns 501, 502, 503, 504, 505, and 506 are not electrically connected at the first surface 1S.

The circuit pattern 500 may include at least one connection pattern CP. The connection pattern CP may be connected to two circuit patterns among the circuit patterns 501, 502, 503, 504, 505, and 506.

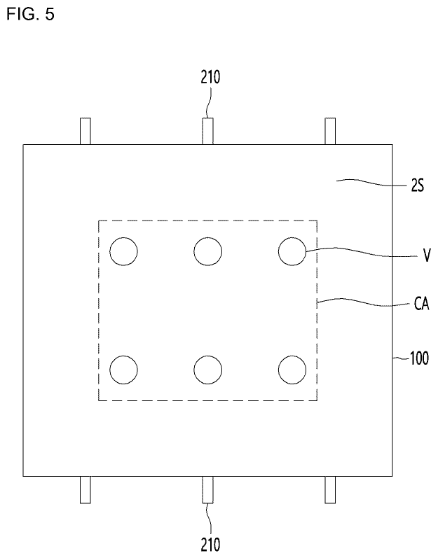

Referring to FIG. 5, the second surface 2S may include a chip mounting region CA. A plurality of vias V may be formed in the chip mounting region CA. The via V passes through the first surface 1S and the second surface 2S. Also, the via V includes a conductive material.

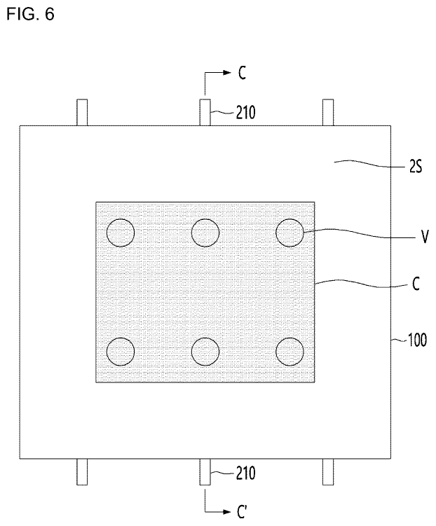

For example, the via V may be formed in regions corresponding to the circuit patterns 501, 502, 503, 504, 505, and 506. Referring to FIG. 6, a chip C is disposed in the chip mounting region CA. The chip C may be electrically connected to the circuit patterns 501, 502, 503, 504, 505, and 506 through the via V.

For example, the chip C may be wire-bonded to the circuit patterns 501, 502, 503, 504, 505, and 506 by the via V, the wire 600, and a pad part 530.

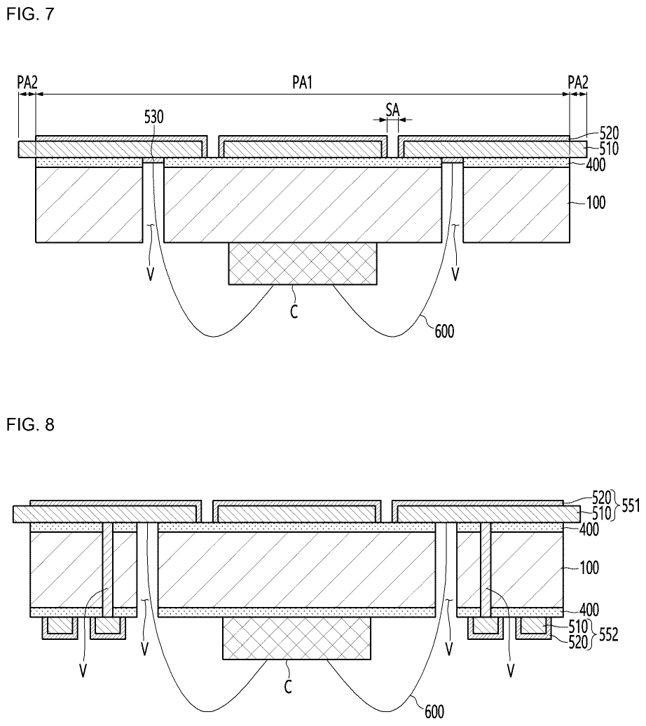

Referring to FIG. 7, the circuit pattern 500 may include a first pattern region PA1 and a second pattern region PA2.

The first pattern region PA1 and the second pattern region PA2 may be connected to each other. Also, the first pattern region PA1 and the second pattern region PA2 may be integrally formed.

The first pattern region PA1 may be disposed on the substrate 100. That is, the first pattern region PA1 overlaps the substrate 100 in a thickness direction of the substrate 100.

Also, the second pattern region PA2 may not be disposed on the substrate 100. Specifically, the second pattern region PA1 may be disposed outside the substrate 100. That is, the second pattern region PA2 does not overlap the substrate 100 in the thickness direction of the substrate 100.

The first pattern region PA1 may be a circuit layer disposed on the substrate 100. Also, the second pattern region PA2 may be a part of the second conductive layer 220 that remains when the smart IC module substrate is cut.

Accordingly, the first pattern region PA1 and the second pattern region PA2 may include different thicknesses, line widths, and materials.

In detail, the first pattern region PA1 and the second pattern region PA2 may include different materials.

Specifically, the first pattern region PA1 may include the first metal layer 510 and the second metal layer 520 described above. The second pattern region PA2 may include only the first metal layer 510. That is, the second pattern region PA2 does not include the second metal layer 520.

Also, the first pattern region PA1 and the second pattern region PA2 may have different thicknesses. Specifically, the thickness of the first pattern region PA1 may be greater than the thickness of the second pattern region PA2.

That is, the first pattern region PA1 further includes the second metal layer. Accordingly, the thickness of the first pattern region PA1 may be greater than the thickness of the second pattern region PA2. For example, the thickness of the first pattern region PA1 may be greater than the thickness of the second pattern region PA2 by less than or equal to the thickness of the second metal layer 520.

Also, the first pattern region PA1 and the second pattern region PA2 may have different line widths. Specifically, the line width of the second pattern region PA2 may be greater or less than the line width of the first pattern region PA1.

Specifically, the line width of the second pattern region PA2 may be less than the line width of the circuit pattern of the first pattern region PA1. Also, the line width of the second pattern region PA2 may be greater than or equal to the line width of the connection pattern CP of the first pattern region PA1.

The line width of the connection pattern CP may be the same as or similar to a width of the space region SA. Specifically, the line width of the connection pattern CP may be 0.1 mm to 0.5 mm. More specifically, the line width of the connection pattern CP may be 0.2 mm to 0.4 mm.

As described above, the second plating layer may have a line width within a set range. Accordingly, the thickness of the second metal layer becomes uniform. In this case, the line width of the connection pattern may also be formed within a set range. Accordingly, a current flowing into the circuit layer may be uniformly transferred to the circuit layer. Accordingly, the thickness of the plurality of circuit patterns may be uniformly formed. Also, it is possible to prevent the occurrence of a plating defect or a thickness deviation.

Meanwhile, in the above description, it has been described that the circuit pattern is formed only on the first surface. However, embodiments are not limited thereto.

Referring to FIG. 8, the circuit pattern may also be disposed on the second surface 2S.

For example, the smart IC substrate may include a circuit pattern 551 disposed on the first surface 1S and a circuit pattern 552 disposed on the second surface 2S.

In this case, the circuit patterns 551 and 552 may be electrically connected through a via V.

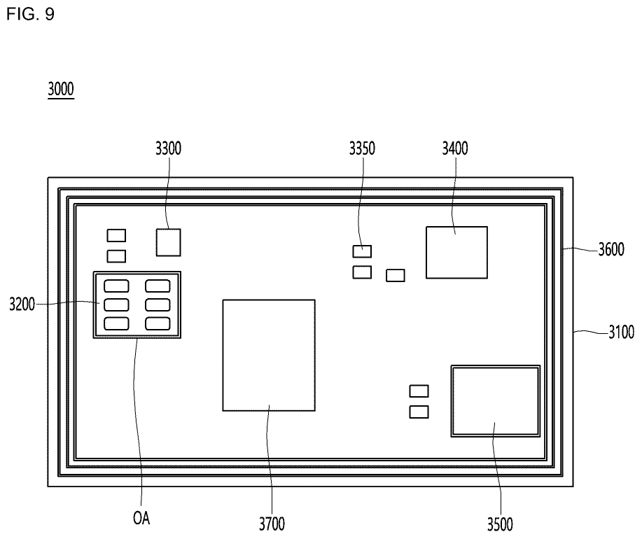

FIG. 9 is a top view of an IC card to which a smart IC substrate according to an embodiment is applied.

Referring to FIG. 9, the IC card 3000 may include a card body 3100, a smart IC substrate 3200, a chip 3300, a microcontroller unit (MCU) 3400, a connection circuit pattern 3350, a fingerprint sensor 3500, an antenna 3600, and a battery 3700. The smart IC substrate 3200, the chip 3300, the microcontroller unit (MCU) 3400, the connection circuit pattern 3350, the fingerprint sensor 3500, the antenna 3600, and the battery 3700 are accommodated in the card body 3100. The connection circuit pattern 3350 electrically connects the chip 3300 to the microcontroller unit 3400.

The card body 3100 includes an opening OA. The smart IC substrate 3200 is disposed inside the opening OA. The smart IC substrate 3200 is attached to the card body 3100. Accordingly, any one of the one surface and the other surface of the smart IC substrate 3200 is exposed to the outside of the IC card.

The chip 3300 stores predetermined user fingerprint information.

The fingerprint sensor 3500 recognizes a user's fingerprint. Also, the recognized fingerprint information is matched with the fingerprint information stored in the chip 3300.

For example, when a user's finger contacts the fingerprint sensor 3500, power is supplied from the battery 3700 to the micro-control unit 3400. The fingerprint sensor 3500 is supplied with power by the micro-control unit 3400. Accordingly, the fingerprint sensor 3500 is driven.

Subsequently, the micro-control unit 3300 receives the fingerprint information recognized by the fingerprint sensor 3500. Subsequently, the authentication process of the recognized fingerprint information proceeds.

Subsequently, when the recognized fingerprint information matches the fingerprint information stored in the chip 3300, the function of the IC card is activated.

On the other hand, if the recognized fingerprint information does not match the fingerprint information stored in the chip 3300, the function of the IC card is deactivated.

However, the embodiment is not limited thereto, and the IC card does not include the fingerprint sensor 3500, that is, the IC card may be activated without separate fingerprint authentication.

The IC card may include an antenna 3600. Accordingly, the IC card may operate as a contactless card. That is, information may be transmitted and received to and from the server without contacting the card reader by the antenna.

However, the embodiment is not limited thereto, and the IC card does not include the antenna 3600. That is, the IC card may operate as a contact type card. That is, the IC card may be inserted into the reader to be in contact with the circuit board. Accordingly, information may be transmitted and received with the server.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. A smart IC substrate module comprising:
a substrate including a first region and a second region disposed on and below the first region;
a circuit layer disposed in the first region; and
a conductive layer disposed in the first region and the second region and connected to the circuit layer, and
wherein the conductive layer includes a plurality of first pattern parts spaced apart from each other in a first direction defined in a longitudinal direction and having a ring shape; and a reinforcing pattern part extending in the first direction between the plurality of first pattern parts, and
wherein the reinforcing pattern part directly connects the plurality of first pattern parts in the first direction.

12. The smart IC substrate module of claim 11, wherein an area of a conductive layer disposed in the second region is 20% to 30% of a total area of the second region.

13. The smart IC substrate module of claim 11, wherein the conductive layer includes:
a first connection pattern part connected to each of the plurality of first pattern parts and positioned farther from the first region than are the plurality of first pattern parts;
a second pattern part spaced apart from the plurality of first pattern parts in a second direction perpendicular to the first direction and extending in the first direction;
a second connection pattern part connecting between the plurality of first pattern parts and the second pattern parts and between the reinforcing pattern parts and the second pattern parts;
a third pattern part extending in the second direction from the second pattern part and disposed closer to the first region than is the second pattern part; and
a fourth pattern part extending from the third pattern part in the first direction.

14. The smart IC substrate module of claim 13, wherein a line width of at least one of the first connection pattern part, the second connection pattern part, the first pattern part, the second pattern part, the third pattern part, or the fourth pattern part is 0.3 mm to 0.7 mm.

15. The smart IC substrate module of claim 13, wherein the first connection pattern part, the second connection pattern part, the first pattern part, and the second pattern part are disposed only in the second region, and
wherein the third pattern part and the fourth pattern part include a first portion disposed in the first region and a second portion disposed in the second region.

16. The smart IC substrate module of claim 13, wherein the second region includes a plurality of holes spaced apart in the first direction, and
wherein each of the plurality of first pattern parts has a ring shape surrounding the hole.

17. The smart IC substrate module of claim 16, wherein the plurality of first pattern parts includes an opening portion overlapping the hole along a thickness direction, and
wherein the reinforcing pattern part overlaps the opening portion along the first direction.

18. The smart IC substrate module of claim 13, wherein the fourth pattern part includes a first portion extending in the first direction, a second portion extending in the second direction, and a bent portion provided between the first portion and the second portion.

19. The smart IC substrate module of claim 13, wherein a length in the second direction of the first connection pattern part is 0.4 mm to 0.8 mm.

20. A smart IC substrate comprising:
a substrate including a first surface and a second surface opposite to the first surface; and
a circuit pattern disposed on the first surface,
wherein the circuit pattern includes a first pattern region and a second pattern region,
wherein the first pattern region overlaps the substrate in a thickness direction of the substrate,
wherein the second pattern region is non-overlapping with the substrate in the thickness direction of the substrate, and
wherein a thickness of the first pattern region is greater than that of the second pattern region.

21. The smart IC substrate of claim 20, wherein the first pattern region includes a first metal layer and a second metal layer disposed on the second metal layer, and
wherein the second pattern region includes the first metal layer.

22. The smart IC substrate of claim 20, wherein the first pattern region includes:
a plurality of circuit patterns disposed to be spaced apart from each other, and
at least one connection pattern connected to the circuit pattern, and
wherein a line width of the connection pattern is 0.1 mm to 0.5 mm.
